(19) United States
(12) Patent Application Publication
(10) Pub. No.: US 2011/0183484 A1
(43) Pub. Date: Jul. 28, 2011

(54) SEMICONDUCTOR DEVICE AND MANUFACTURING METHOD THEREOF

(75) Inventor: Kiyonori OYU, Tokyo (JP)

(73) Assignee: ELPIDA MEMORY, INC., Tokyo (JP)

(21) Appl. No.: 13/079,463

(22) Filed: Apr. 4, 2011

Related U.S. Application Data
(63) Continuation of application No. 11/948,699, filed on Nov. 30, 2007.

(30) Foreign Application Priority Data
Dec. 1, 2006 (JP) 2006-326020

(51) Int. Cl. H01L 21/336

(52) U.S. Cl. 438/270; 257/E21.41

(57) ABSTRACT

A semiconductor device comprises a plurality of semiconductor pillars laid out in matrix in a first and a second directions parallel with a main surface of a semiconductor substrate, and extending to a direction substantially perpendicular to the main surface; gate insulating films covering each surface of the plurality of semiconductor pillars, respectively; upper diffusion layers formed in each upper part of the plurality of semiconductor pillars, respectively; lower diffusion layers formed in each lower part of the plurality of semiconductor pillars, respectively; gate electrodes encircling at least each channel region between each upper diffusion layer and each lower diffusion layer, respectively; and a plurality of lower electrodes short-circuiting the lower diffusion layers adjacent in the first direction.

This is a Continuation of application Ser. No. 11/948,699 filed Nov. 30, 2007, claiming priority based on Japanese Patent Application No. 2006-326020 filed Dec. 1, 2006, the contents of all of which are incorporated herein by reference in their entirety.

### TECHNICAL FIELD

The present invention relates to a semiconductor device and a manufacturing method thereof, and more particularly to a semiconductor device having plural transistors laid out in matrix, and a manufacturing method thereof.

### BACKGROUND OF THE INVENTION

Integration of a semiconductor device has so far been achieved by mainly miniaturization of transistors. Miniaturization of transistors has substantially reached a limit. When a transistor size is decreased any more, there is a risk that the transistors cannot operate normally due to short channel effect or the like.

In order to fundamentally solve these problems, there have been proposed methods of three-dimensionally forming transistors, by three-dimensionally processing a semiconductor substrate. Among transistors formed by these methods, a three-dimensional transistor, using a semiconductor pillar extending in a perpendicular direction to the main surface of the semiconductor substrate as a channel, has an advantage in that an occupied area is small and that a large drain current can be obtained by fully-depletion of the transistor (see Japanese Patent Application Laid-open Nos. H6-209089, H9-8295 and 2002-83945).

When the conventional three-dimensional transistors are laid out in matrix, upper diffusion layers formed in an upper part of the semiconductor pillar can be connected together using a low-resistance material. However, lower diffusion layers formed in a lower part of the semiconductor pillar are connected together based on a contact between adjacent lower diffusion layers by themselves. Consequently, because the diffusion layer resistance limits the connection resistance of the lower diffusion layers, power consumption increases, and high-speed operation cannot be easily performed.

Further, the conventional three-dimensional transistors have a problem such that positive charge is accumulated within the semiconductor pillar by switching, and this causes a variation of a threshold voltage.

### SUMMARY OF THE INVENTION

It is therefore an object of the present invention to provide a semiconductor device capable of decreasing a wiring resistance for connecting between lower diffusion layers of a three-dimensional transistor, and a manufacturing method thereof.

Another object of the present invention is to provide a semiconductor device capable of minimizing accumulation of positive charge within a semiconductor pillar constituting a three-dimensional transistor.

The semiconductor device according to one aspect of the present invention comprises a plurality of semiconductor pillars laid out in matrix in a first and a second directions parallel with a main surface of a semiconductor substrate, and extending to a direction substantially perpendicular to the main surface; gate insulating films covering each surface of the plurality of semiconductor pillars, respectively; upper diffusion layers formed in each upper part of the plurality of semiconductor pillars, respectively; lower diffusion layers formed in each lower part of the plurality of semiconductor pillars, respectively; gate electrodes encircling at least each channel region between each upper diffusion layer and each lower diffusion layer, respectively; and a plurality of lower electrodes short-circuiting the lower diffusion layers adjacent in the first direction.

It is preferable that the plurality of semiconductor pillars are provided on projections provided on the semiconductor substrate, respectively, and the lower electrodes are provided along sidewalls of the projections. In this case, the projections may have a plurality of belt shapes extended to the first direction, thereby the lower electrodes are continuously provided in the first direction. Alternatively, the projections may have a plurality of island shapes laid out in matrix in the first and the second directions so that each one of the lower electrode is provided for each one of the lower diffusion layers.

The semiconductor device according to another aspect of the present invention comprises: a semiconductor pillar extending to a direction substantially perpendicular to a main surface of a semiconductor substrate; a gate insulating film covering a surface of the semiconductor pillar; an upper diffusion layer formed in an upper part of the semiconductor pillar; a lower diffusion layer formed in a lower part of the semiconductor pillar; and a gate electrode encircling at least a channel region between the upper diffusion layer and the lower diffusion layer, wherein the lower diffusion layer is formed in the lower external periphery part of the semiconductor pillar, and a discharge layer connecting the channel region to the semiconductor substrate is formed in the lower center part of the semiconductor pillar.

The method of manufacturing a semiconductor device according to one aspect of the present invention comprises: a first step of forming a trench and a projection in a semiconductor substrate by etching the semiconductor substrate; a second step of forming a lower electrode on the bottom of the trench; a third step of covering the lower electrode with an insulating film; a fourth step of forming a semiconductor pillar in the semiconductor substrate by etching a part of the projection; a fifth step of forming a gate insulating film to cover a surface of the semiconductor pillar; and a sixth step of forming an upper diffusion layer and a lower diffusion layer in an upper part and a lower part of the semiconductor pillar, respectively, wherein at the sixth step, the lower diffusion layer is formed to be in contact with the lower electrode.

In the present invention, at least the fifth step and the sixth step maybe performed in any order. It is preferable that the method of manufacturing a semiconductor device according to the present invention further comprises a seventh step of forming a discharge layer that connects a channel region between the upper diffusion layer and the lower diffusion layer to the semiconductor substrate.

The method of manufacturing a semiconductor device according to another aspect of the present invention comprises: a first step of forming a semiconductor pillar on a semiconductor substrate; a second step of forming a gate insulating film covering a surface of the semiconductor pillar; a third step of forming an upper diffusion layer and a lower diffusion layer in an upper part and a lower part of the semiconductor pillar, respectively; and a fourth step of forming a discharge layer that connects a channel region between the upper diffusion layer and the lower diffusion layer to the semiconductor substrate.

In the present invention, at least the third step and the fourth step may be performed in any order. At the third step, a one-conductive impurity can be ion-implanted, and at the fourth step, a reverse-conductive impurity can be ion-implanted deeper than the one-conductive impurity.

As described above, a semiconductor device according to one aspect of the present invention includes plural lower electrodes that mutually short-circuit lower diffusion layers adjacent to a first direction. Therefore, the wiring resistance of wirings that connect between the lower diffusion layers can be substantially decreased. As a result, when a memory cell array is configured having bit lines at the lower diffusion layer side, for example, power consumption can be decreased by decreasing the bit line resistance, and a high-speed operation can be achieved.

In a semiconductor device according to another aspect of the present invention, a discharge layer connecting between a channel region and a semiconductor substrate is formed at a center portion of a lower part of a semiconductor pillar. Therefore, positive charge generated within the semiconductor pillar can be quickly discharged via the discharge layer. Accordingly, a variation in a threshold voltage due to the accumulation of positive charge can be prevented.

In a manufacturing method of a semiconductor device according to the present invention, a semiconductor device having the above characteristics can be easily manufactured.

### BRIEF DESCRIPTION OF THE DRAWINGS

The above and other objects, features and advantages of this invention will become more apparent by reference to the following detailed description of the invention taken in conjunction with the accompanying drawings, wherein:

FIGS. 1A to 1C show relevant parts of a semiconductor device according to a first embodiment of the present invention, where FIG. 1A is a top plan view of the semiconductor device, FIG. 1B is a cross-sectional view of FIG. 1A cut along a line B-B, and FIG. 1C is a cross-sectional view of FIG. 1A cut along a line C-C;

FIG. 2 is a schematic perspective view for explaining a shape of a semiconductor substrate 100;

FIG. 3 is a circuit diagram of the semiconductor device shown in FIGS. 1A to 1C;

FIG. 4 is a circuit diagram when the semiconductor device according to the first embodiment is used as a memory cell array of a DRAM;

FIGS. 5A to 5C are views for explaining a process (formation of a silicon oxide film to formation of a silicon oxide film) in the manufacturing method of the semiconductor device according to the first embodiment;

FIGS. 6A to 6C are views for explaining a process (etching back of the silicon oxide film) in the manufacturing method of the semiconductor device according to the first embodiment;

FIGS. 7A to 7C are views for explaining a process (formation of a lower electrode) in the manufacturing method of the semiconductor device according to the first embodiment;

FIGS. 8A to 8C are views for explaining a process (formation of a silicon oxide film) in the manufacturing method of the semiconductor device according to the first embodiment;

FIGS. 9A to 9C are views for explaining a process (formation of a mask pattern) in the manufacturing method of the semiconductor device according to the first embodiment;

FIGS. 10A to 10C are views for explaining a process (patterning of the silicon nitride film) in the manufacturing method of the semiconductor device according to the first embodiment;

FIGS. 11A to 11C are views for explaining a process (removal of the mask pattern) in the manufacturing method of the semiconductor device according to the first embodiment;

FIGS. 12A to 12C are views for explaining a process (etching of the silicon oxide films) in the manufacturing method of the semiconductor device according to the first embodiment;

FIGS. 13A to 13C are views for explaining a process (etching of the semiconductor substrate) in the manufacturing method of the semiconductor device according to the first embodiment;

FIGS. 14A to 14C are views for explaining a process (formation of a gate insulating film, an upper diffusion layer, a lower diffusion layer, P-type impurity layers) in the manufacturing method of the semiconductor device according to the first embodiment;

FIGS. 15A to 15C are views for explaining a process (formation of a gate electrode material) in the manufacturing method of the semiconductor device according to the first embodiment;

FIGS. 16A to 16C are views for explaining a process (formation of a gate electrode) in the manufacturing method of the semiconductor device according to the first embodiment;

FIGS. 17A to 17C show relevant parts of a semiconductor device according to a second embodiment, where FIG. 17A is a top plan view of the semiconductor device, FIG. 17B is a cross-sectional view of FIG. 17A cut along the line B-B, and FIG. 17C is a cross-sectional view of FIG. 17A cut along the line C-C;

FIG. 18 is a schematic perspective view for explaining the shape of the semiconductor substrate according to the second embodiment;

FIGS. 19A to 19C are views for explaining a process (formation of a silicon oxide film to formation of a silicon oxide film) in the manufacturing method of the semiconductor device according to the second embodiment;

FIGS. 20A to 20C are views for explaining a process (etching back of the silicon oxide film) in the manufacturing method of the semiconductor device according to the second embodiment;

FIGS. 21A to 21C are views for explaining a process (formation of a lower electrode) in the manufacturing method of the semiconductor device according to the second embodiment;

FIGS. 22A to 22C are views for explaining a process (formation of a silicon oxide film) in the manufacturing method of the semiconductor device according to the second embodiment;

FIGS. 23A to 23C are views for explaining a process (formation of a mask pattern) in the manufacturing method of the semiconductor device according to the second embodiment;

FIGS. 24A to 24C are views for explaining a process (patterning of the silicon nitride film) in the manufacturing method of the semiconductor device according to the second embodiment;

FIGS. 25A to 25C are views for explaining a process (removal of the mask pattern) in the manufacturing method of the semiconductor device according to the second embodiment;

FIGS. 26A to 26C are views for explaining a process (etching of the silicon oxide films) in the manufacturing method of the semiconductor device according to the second embodiment;

FIGS. 27A to 27C are views for explaining a process (etching of the semiconductor substrate) in the manufacturing method of the semiconductor device according to the second embodiment;

FIGS. 28A to 28C are views for explaining a process (formation of a gate insulating film, an upper diffusion layer, a lower diffusion layer, P-type impurity layers) in the manufacturing method of the semiconductor device according to the second embodiment;

FIGS. 29A to 29C are views for explaining a process (formation of a gate electrode material) in the manufacturing method of the semiconductor device according to the second embodiment; and

FIGS. 30A to 30C are views for explaining a process (formation of a gate electrode) in the manufacturing method of the semiconductor device according to the second embodiment.

### DETAILED DESCRIPTION OF THE EMBODIMENTS

Preferred embodiments of the present invention will be explained below in detail with reference to the accompanying drawings.

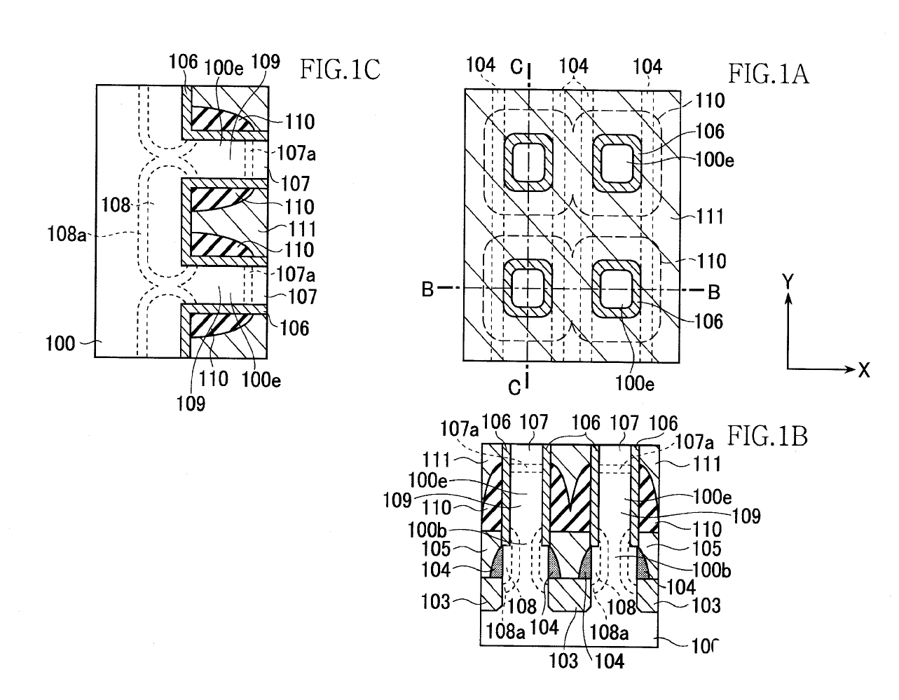

FIGS. 1A to 1C show relevant parts of a semiconductor device according to a first embodiment of the present invention. FIG. 1A is a top plan view of the semiconductor device, FIG. 1B is a cross-sectional view of FIG. 1A cut along a line B-B, and FIG. 1C is a cross-sectional view of FIG. 1A cut along a line C-C.

As shown in FIGS. 1A to 1C, the semiconductor device according to the first embodiment includes a plurality of semiconductor pillars 100e disposed in matrix in the X direction and the Y direction parallel with the main surface of a semiconductor substrate 100. The semiconductor pillars 100e are a part of the semiconductor substrate 100, and are extended to a direction perpendicular to the main surface of the semiconductor substrate 100. An upper diffusion layer 107 is formed in an upper part of each semiconductor pillar 100e, and a lower diffusion layer 108 is formed in a lower part of the semiconductor pillar 100e. Side surface of the semiconductor pillar 100e is covered with a gate insulating film 106 over a whole periphery.

One of the upper diffusion layer 107 and the lower diffusion layer 108 works as one of a source region and a drain region, and the other of the upper diffusion layer 107 and the lower diffusion layer 108 works as the other of the source region and the drain region. In the semiconductor pillar 100e, a region between the upper diffusion layer 107 and the lower diffusion layer 108 functions as a channel region 109. As explained above, the semiconductor pillar 100e constitutes a main part of a three-dimensional transistor.

In the first embodiment, the interval between the adjacent semiconductor pillars 100e in the X direction is set smaller than the interval between the adjacent semiconductor pillars 100e in the Y direction. A plane shape of the semiconductor pillar 100e is substantially square (or circular). Therefore, the layout pitch of the semiconductor pillars 100e in the X directions is smaller than the layout pitch of the semiconductor pillars 100e in the Y direction.

A gate electrode 110 encircling the channel region 109 is provided between the adjacent semiconductor pillars 100e. The adjacent gate electrodes 110 are brought into contact with each other in the X direction, and are not brought into contact with each other in the Y direction. Accordingly, the gate electrodes 110 of the three-dimensional transistors adjacent in the X direction are common to each other, and the gate electrodes 110 of the three-dimensional transistors adjacent in the Y direction are mutually separate.

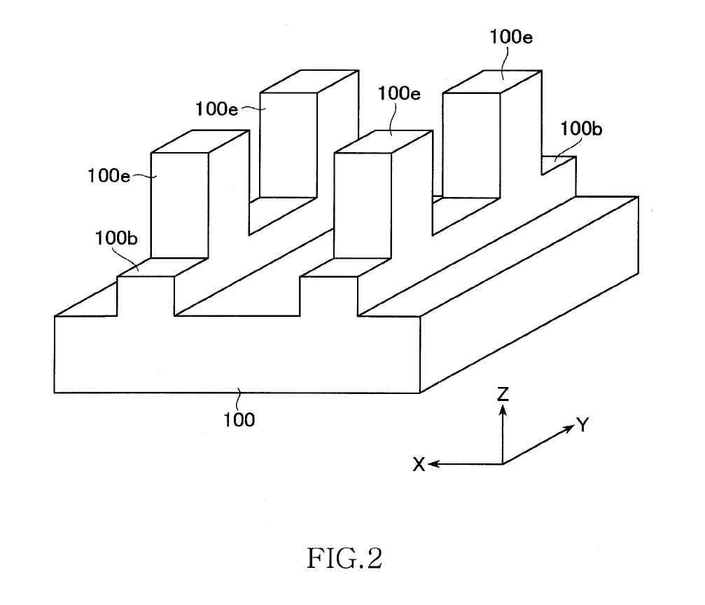

FIG. 2 is a schematic perspective view for explaining a shape of the semiconductor substrate 100. As shown in FIG. 2, on the semiconductor substrate 100, plural belt-shaped projections 100b are provided to extend to the Y direction. The semiconductor pillars 100e extending to the Z direction are provided on these projections 110b.

Referring back to FIGS. 1A to 1C, a lower electrode 104 continuously extending to the Y direction is provided on the sidewall of the projection 110b. The lower electrode 104 plays the role of short-circuiting the lower diffusion layers 108 adjacent in the Y direction, thereby decreasing the wiring resistance of wirings connecting between the lower diffusion layers 108.

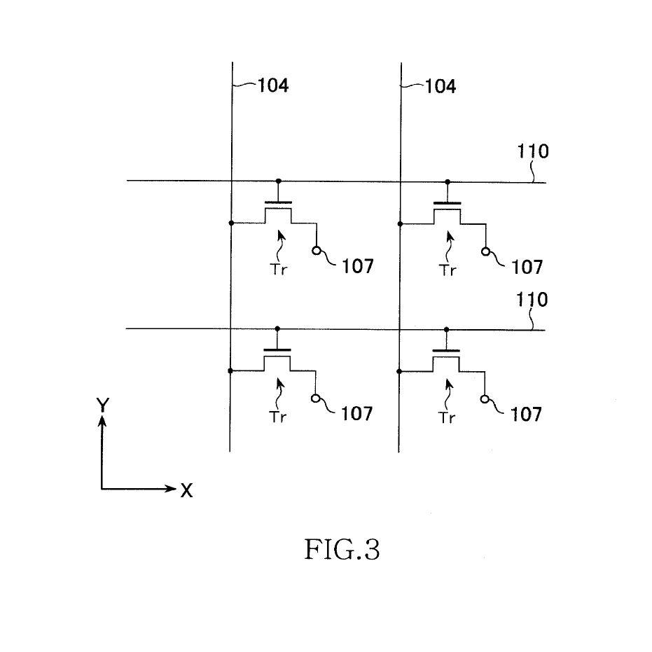

FIG. 3 is a circuit diagram of the semiconductor device shown in FIGS. 1A to 1C.

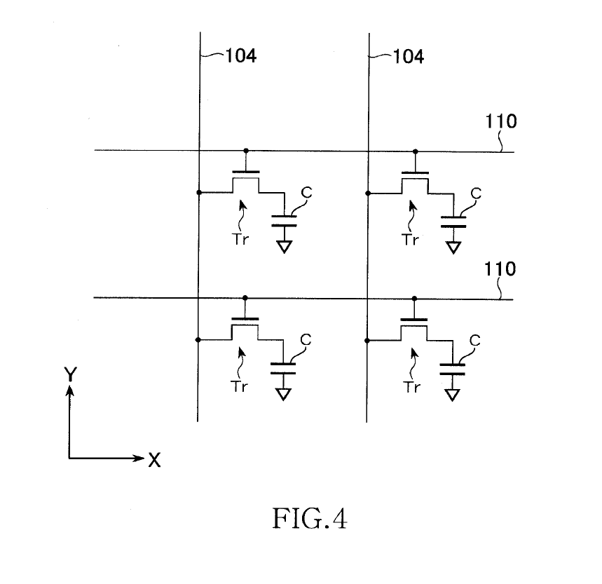

As shown in FIG. 3, the semiconductor device shown in FIGS. 1A to 1C has an array structure, having plural gate electrodes 110 extending to the X direction, intersected with plural lower electrodes 104 extending to the Y direction, and having three-dimensional transistors laid out at these intersections. While the use of this semiconductor device is not particularly limited, the semiconductor device can be used as a memory cell array of a DRAM, when a capacitor C is connected to each upper diffusion layer 107, as shown in FIG. 4.

In the first embodiment, while four three-dimensional transistors are laid out in the matrix of 2×2 to facilitate the understanding, it is needless to mention that more transistors can be laid out in matrix.

A manufacturing method of the semiconductor device according to the first embodiment is explained next.

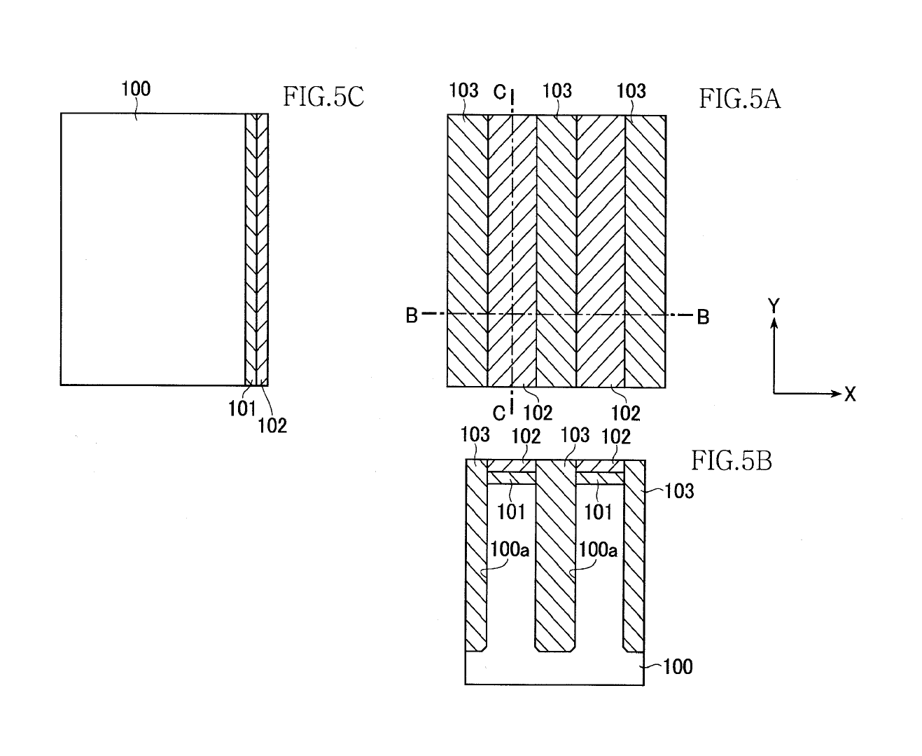

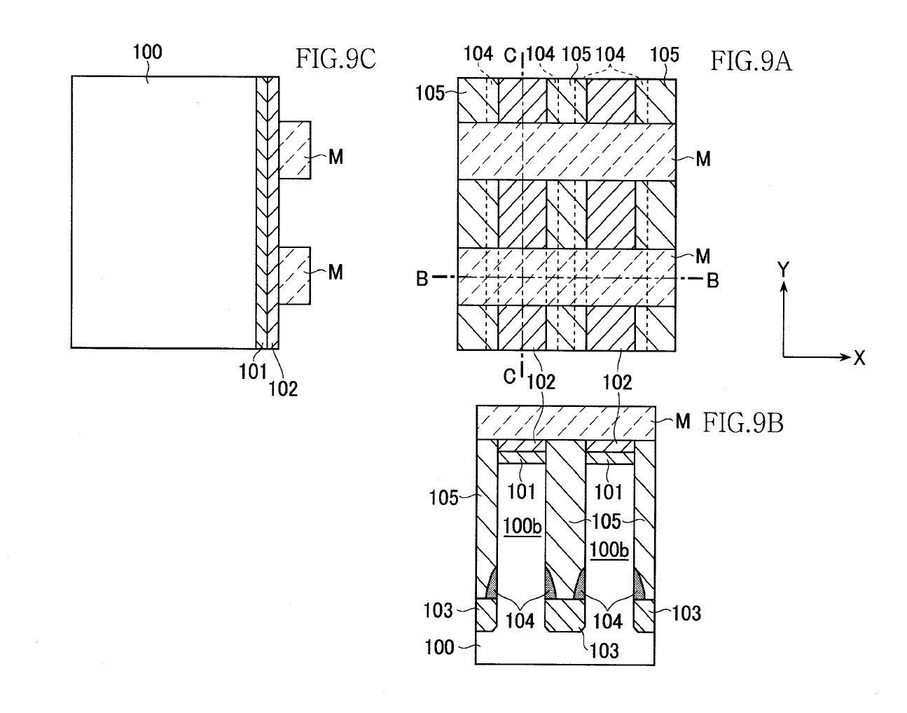

FIGS. 5 to 16 are process views for explaining the manufacturing method of the semiconductor device according to the first embodiment. In each set of these drawings, A expresses a top plan view, B expresses a cross-sectional view cut along a line B-B of A, and C expresses a cross-sectional view cut along a line C-C of A.

First, as shown in FIGS. 5A to 5C, a silicon oxide film 101 and a silicon nitride film 102 are formed on the surface of the semiconductor substrate 100 made of P-type silicon. Thereafter, the silicon nitride film 102 is patterned by dry etching using a photoresist (not shown), thereby forming a belt-shaped body extending to the Y direction. Next, the silicon oxide film 101 and the semiconductor substrate 100 are etched, using the patterned silicon nitride film 102 as a mask, thereby forming a trench 100a extending to the Y direction within the semiconductor substrate 100. A projection made of the semiconductor substrate 100 is formed between the trenches 100a adjacent to the X direction.

The trench 100a is embedded with a silicon oxide film 103 by depositing the silicon oxide film 103 on the whole surface. Thereafter, the surface is ground according to the CMP (Chemical Mechanical Polishing) method, thereby obtaining a configuration as shown in FIGS. 5A to 5C. Alternatively, the silicon oxide film 103 can be embedded into the trench 100a according to the HDD (High-Density Plasma)-CVD method. In the grinding according to the CMP method, the silicon nitride film 102 can be used as a stopper.

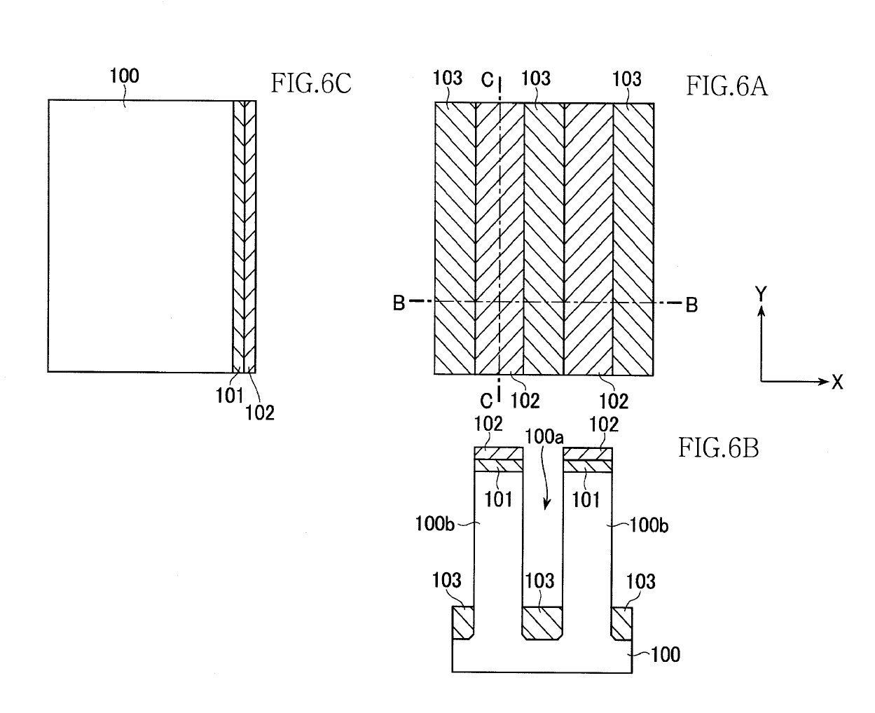

Thereafter, as shown in FIGS. 6A to 6C, the silicon oxide film 103 is etched back to keep the silicon oxide film 103 left at only the bottom of the trench 100a. The silicon oxide film 103 needs to be etched back, in a condition that a selection rate to the silicon nitride film 102 is high. With this arrangement, the belt-shaped projection 100b extending to the Y direction is formed on the semiconductor substrate 100. The remaining silicon oxide film 103 becomes an STI (Shallow Trench Isolation) region, and plays the role of achieving element isolation of the three-dimensional transistors adjacent in the X direction.

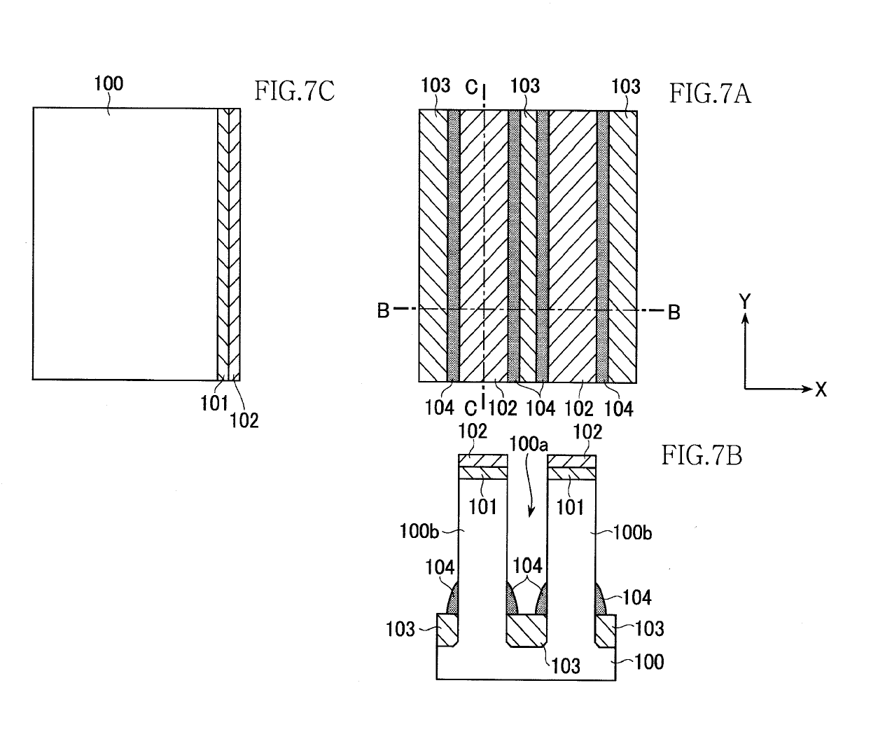

Next, as shown in FIGS. 7A to 7C, a lower electrode material is deposited on the whole surface, and then is etched back. With this arrangement, the lower electrodes 104 remain on only the sidewalls of the projection 100b, on the silicon oxide film 103 remaining on the bottom of the trench 100a. In other words, the lower electrodes 104 have plural belt shapes continuously extending to the Y direction along the sidewalls of the projection 100b. While the material of the lower electrode 104 is not particularly limited, polycrystalline silicon can be used for this material, for example.

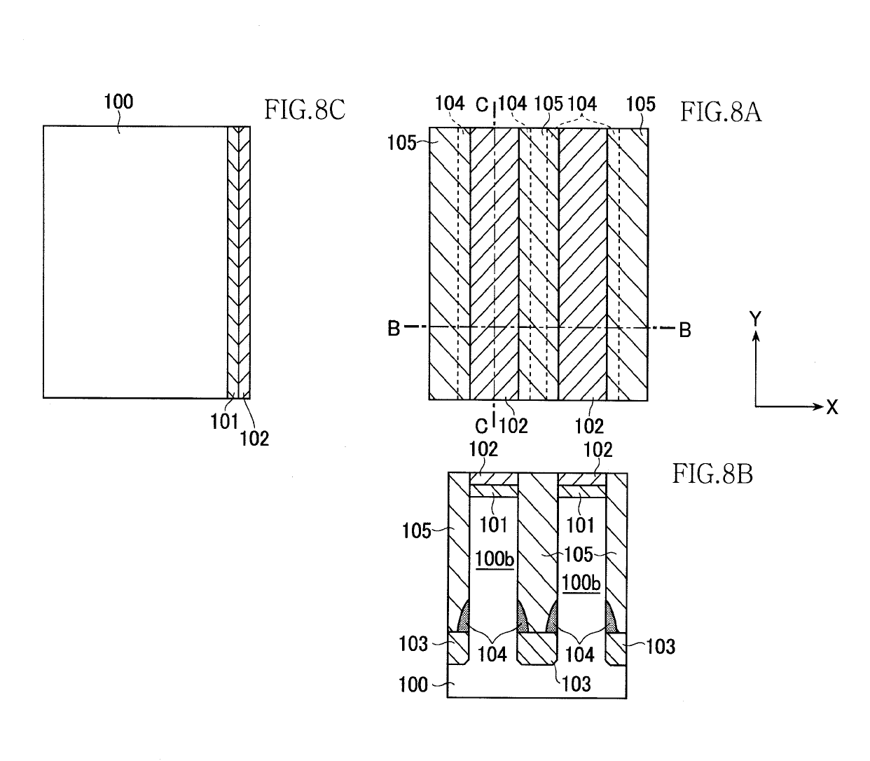

A silicon oxide film 105 is deposited on the whole surface, and is then ground by the CMP method, thereby obtaining a structure as shown in FIGS. 8A to 8C. Also in this case, the silicon nitride film 102 can be used as a stopper. Thereafter, the photoresist is exposed to form a belt-shaped mask pattern M extending to the X direction. Accordingly, the projection 100b extending to the Y direction and the mask pattern M extending to the X direction are intersected.

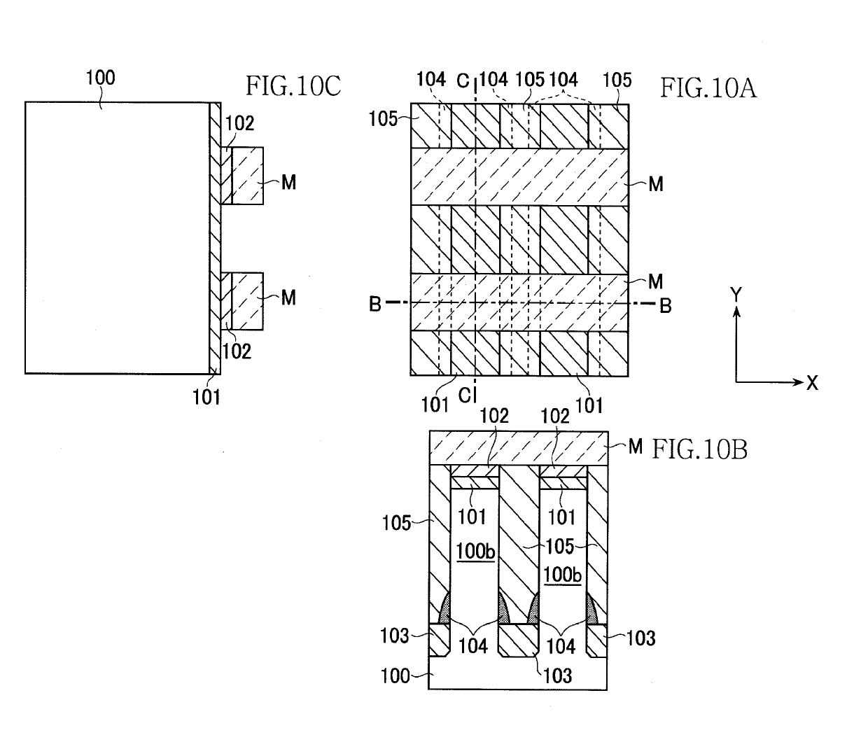

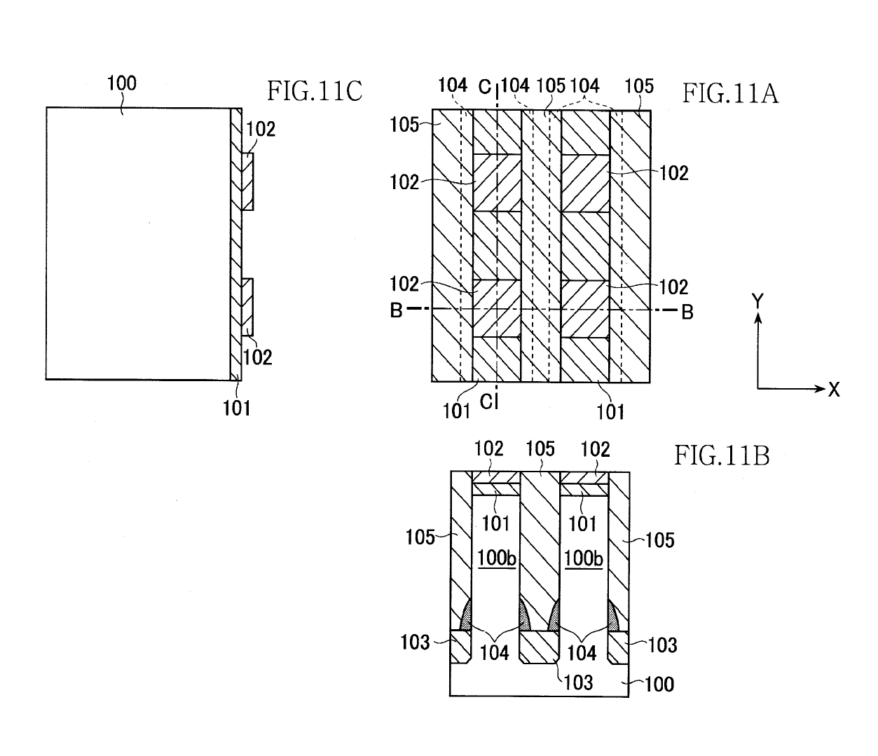

Next, as shown in FIGS. 10A to 10C, the silicon nitride film 102 is etched using the mask pattern M. As a result, the silicon oxide film 101 not covered by the mask pattern M is exposed, and the silicon nitride film 102 is left at only the intersection between the projection 100b and the mask pattern M. In other words, the silicon nitride film 102 is laid out in matrix to the X direction and the Y direction. Thereafter, the mask pattern M is removed, as shown in FIGS. 11A to 11C.

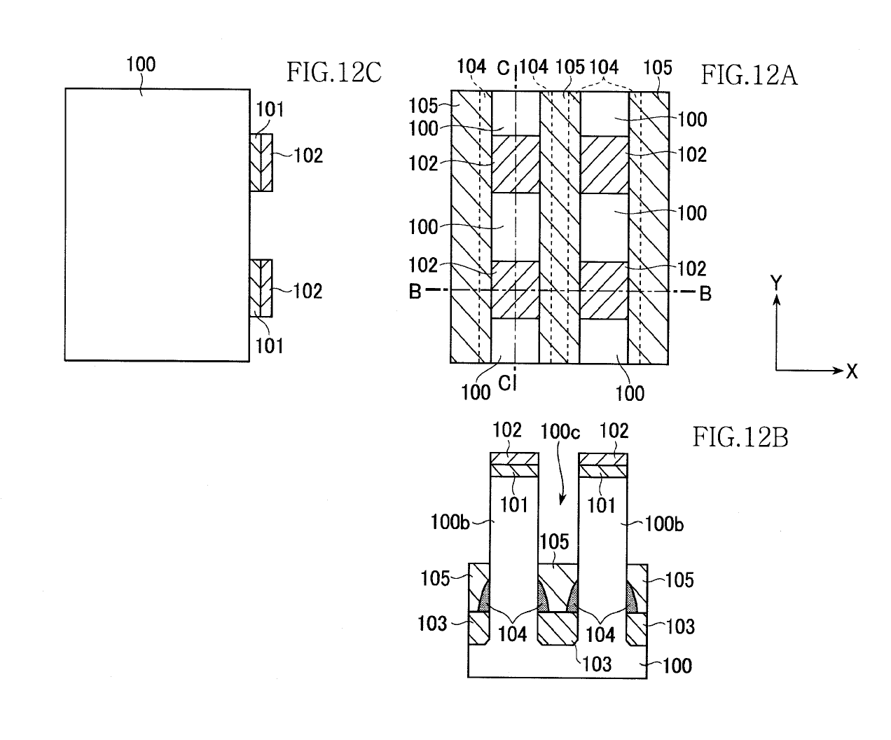

Next, as shown in FIGS. 12A to 12C, the silicon oxide films 101 and 105 are etched, using the silicon nitride film 102 laid out in matrix, as a mask. In this etching, the etching amount of the silicon oxide film 105 needs to be adjusted so as not to expose the lower electrode 104. As a result, the silicon oxide film 101 and the silicon nitride film 102 are laid out in matrix to the X direction and the Y direction, thereby forming a trench 100c extending to the Y direction. The lower electrode 104 is covered with the silicon oxide film 105.

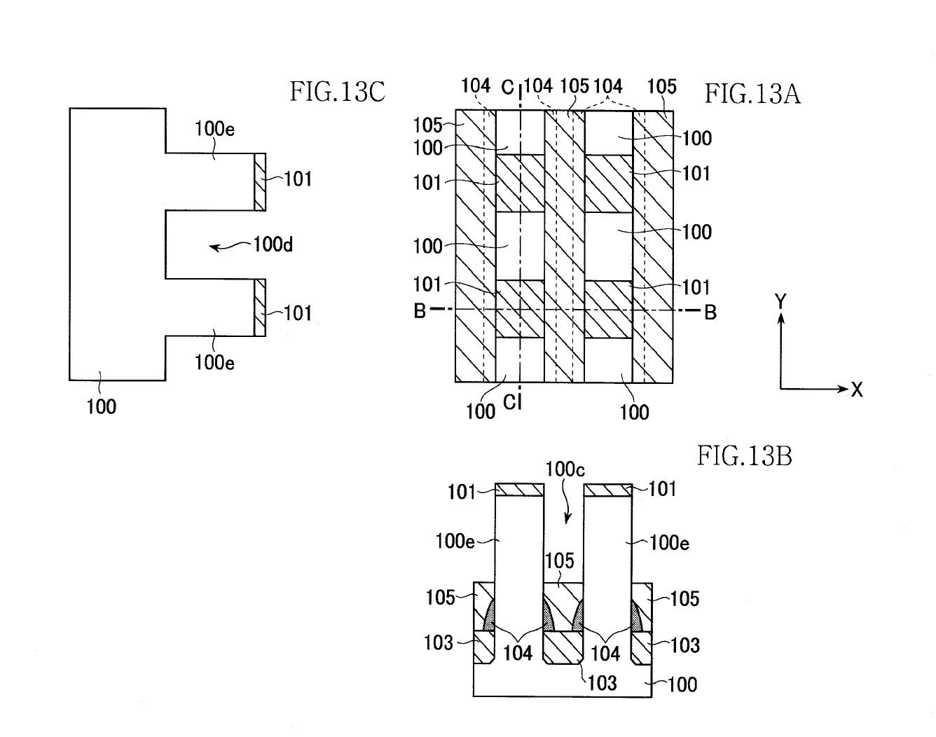

Next, as shown in FIGS. 13A to 13C, the semiconductor substrate 100 is etched, using the silicon oxide film 101 as a mask. In this etching, the silicon nitride film 102 does not need to be removed beforehand, and is removed in the process of etching the semiconductor substrate 100. Accordingly, a trench 100d is formed between the silicon oxide films 101 adjacent in the Y direction. It is preferable that the etching amount of the semiconductor substrate 100 is set equal to that of the trench 100c.

A part of the projection 100b is ground by the above process, thereby having the plural semiconductor pillars 100e, extending to the direction perpendicular to the main surface of the semiconductor substrate 100, disposed in matrix to the X direction and the Y direction. In other words, the semiconductor substrate 100 has the shape as shown in FIG. 2.

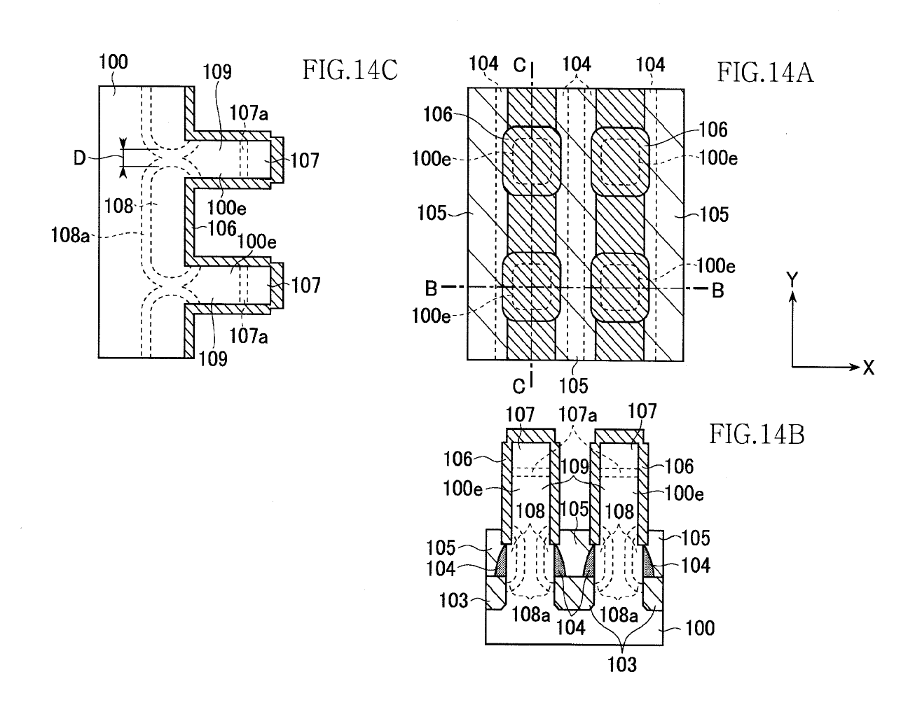

As shown in FIGS. 14A to 14C, the gate insulating film 106 is formed by thermal oxidizing the surface of the exposed semiconductor substrate 100. As a result, all side surfaces of the semiconductor pillars 100e are covered with the gate insulating film 106. An N-type impurity such as phosphorus (P) is ion-implanted into the semiconductor pillar 100e to form the upper diffusion layer 107 in the upper part and the lower diffusion layer 108 in the lower part of the semiconductor pillar 100e, respectively. In this case, it is preferable to form the diffusion layers 107 and 108 by ion-implanting the N-type impurity, after forming a sacrifice oxide film for ion implantation by thermal oxidation, and thereafter, form the gate insulating film 106 by thermal oxidation. The upper diffusion layer 107 and the lower diffusion layer 108 can be formed by separate ion implantations. In this case, the lower diffusion layer 108 is first formed by providing an implantation mask in the upper part of the semiconductor pillar 100e, then form the structure as shown in FIGS. 1A to 1C, and finally form the upper diffusion layer 107 by performing the ion implantation again.

Because the lower diffusion layer 108 is formed by the wraparound of dopant based on the ion implantation, the lower diffusion layer 108 is formed at the lower external periphery of the semiconductor pillar 100e. In this case, the lower part of the semiconductor pillar 100e is not blocked up by the lower diffusion layer 108, but a clearance D in which the lower diffusion layer 108 is not present is formed, as shown in FIG. 14C.

A P-type impurity such as boron (B) is ion-implanted into the semiconductor pillar 100e to form P-type impurity layers 107a and 108a in the upper part and the lower part of the semiconductor pillar 100e, respectively. The P-type impurity is ion-implanted in a condition that the dopant is implanted deeper than the ion implantation of the N-type impurity. As a result, the P-type impurity layer 108a is formed in the clearance D. This P-type impurity layer 108a functions as a discharge layer that connects the channel region 109 to the semiconductor substrate 100. The P-type impurity layer 108a plays the role of preventing the channel region 109 from becoming in the floating state. As a result, a variation (a reduction) of the threshold voltage due to the accumulation of the positive charge in the channel region 109 is suppressed. In order to sufficiently exhibit the function of the discharge layer, preferably, the impurity concentration of the P-type impurity layer 108a is set higher than the impurity concentration of the channel region 109. The P-type impurity layer 107a is not necessary. To eliminate this P-type impurity layer 107a, an implantation mask is provided in the upper part of the semiconductor pillar 100e, at the time of forming the lower P-type impurity layer 108a.

After the formation of the gate insulating film 106, the ion implantation of the N-type impurity and the ion implantation of the P-type impurity do not need to be performed in this order, and can be performed in any order.

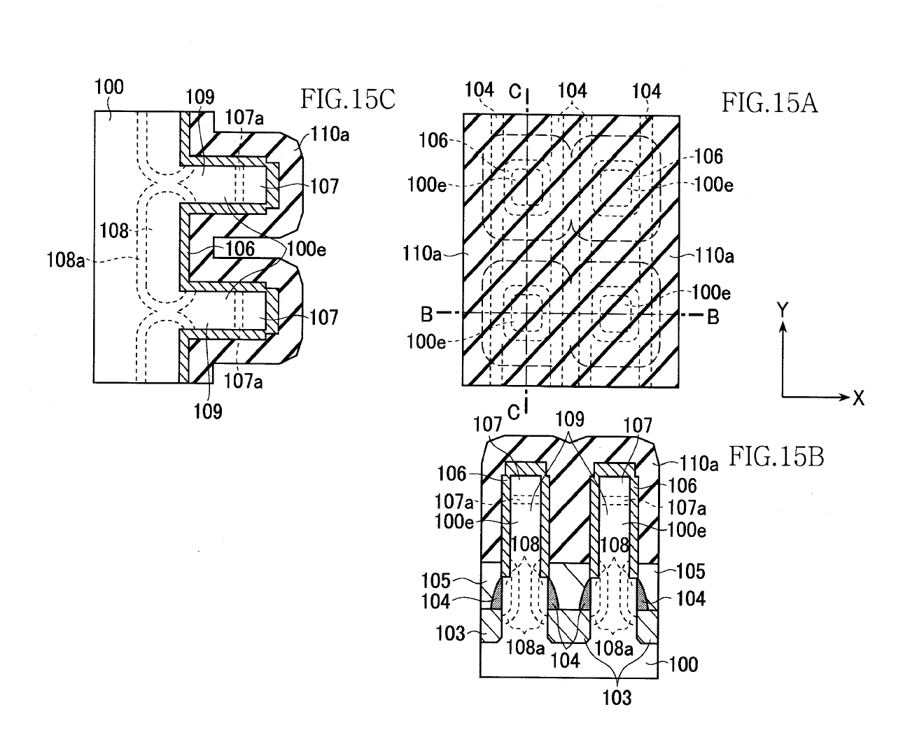

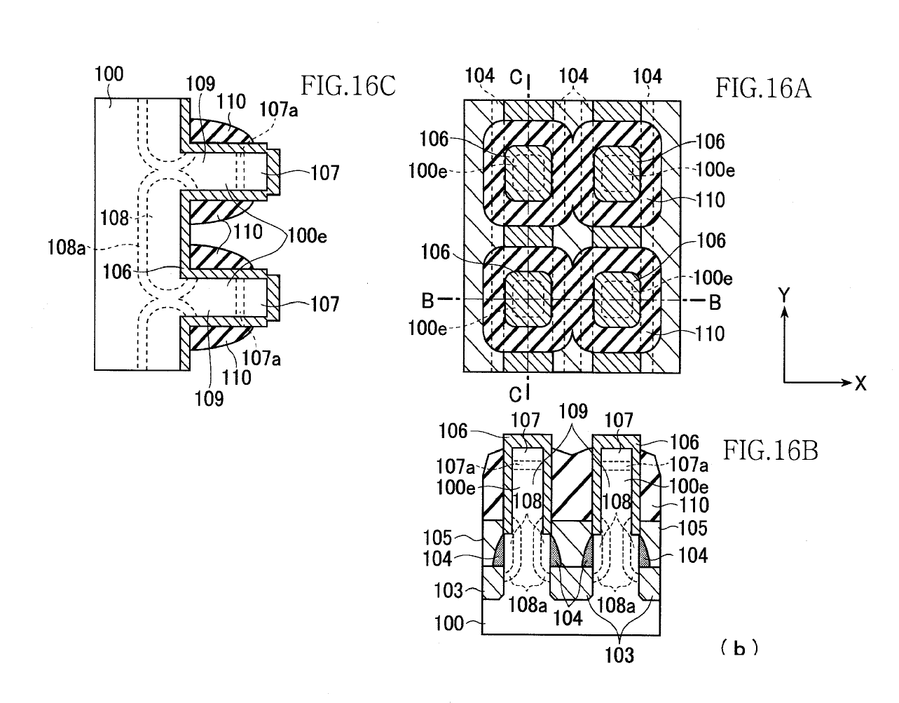

Next, as shown in FIGS. 15A to 15C, a gate electrode material 110a is deposited on the whole surface, thereby covering the whole surface of the semiconductor pillar 100e. Polycrystalline silicon can be used for the gate electrode material 110a. As shown in FIGS. 16A to 16C, the gate electrode material 110a is etched back to form the gate electrode 110. The gate electrode material 110a is etched back until the gate insulating film 106 present between the semiconductor pillars 100e adjacent in the Y direction is exposed. As described above, the interval between the semiconductor pillars 100e in the X direction is set smaller than that in the Y direction. Therefore, while the gate electrodes 110 adjacent in the Y direction are not in contact with each other, the gate electrodes 110 adjacent in the X direction are in contact with each other.

After a silicon oxide film 111 is deposited on the whole surface, the surface is ground by the CMP method, thereby obtaining the structure shown in FIGS. 1A to 1C. In the grinding according to the CMP method, the semiconductor pillar 100e made of silicon can be used as a stopper.

Thereafter, for example, a capacitor is formed on the upper diffusion layer 107 of the semiconductor pillar 100e. The gate electrode 110 and the lower electrode 104 are used as a word line and a bit line, respectively. As a result, this can be used as the memory array of the DRAM, as shown in FIG. 4.

As explained above, in the semiconductor device according to the first embodiment, three-dimensional transistors using the semiconductor pillars 100e are laid out in matrix. The lower diffusion layers 108 adjacent in the Y direction are short-circuited with the lower electrode 104. With this arrangement, the wiring resistance of the wirings connecting between the lower diffusion layers 108 is substantially decreased. Therefore, when a memory cell array using the lower diffusion layer 108 as the bit line is configured, the bit line resistance can be decreased substantially. Consequently, power consumption can be decreased, and a high-speed operation can be performed.

Further, according to the first embodiment, because the lower electrode 104 is continuously provided along the sidewall of the projection 100b, two lower electrodes 104 are allocated to the transistors adjacent in the Y direction. Therefore, the wiring resistance of the wirings that connect between the lower diffusion layers 108 can be decreased sufficiently. Even when one of the two lower electrodes 104 is disconnected, the connection state of the lower electrodes 104 can be secured. Therefore, yield of the product can be increased.

In the first embodiment, the interval between the semiconductor pillars 100e in the X direction is set smaller than that in the Y direction. Therefore, only when the gate electrode material 110a is etched back after it is deposited, the gate electrodes 110 adjacent in the X direction can be in contact with each other, and the gate electrodes 110 adjacent in the Y direction can be set not in contact with each other. In the first embodiment, the planar shape of the semiconductor pillar 100e is substantially square (or circular). Therefore, the layout pitch of the semiconductor pillars 100e in the X directions is smaller than the layout pitch of the semiconductor pillars 100e in the Y direction. While it is not essential to set these layout pitches in the present invention, the setting of these layout pitches makes it possible to increase the integration level.

The P-type impurity layer 108a is formed at the lower center portion of the semiconductor pillar 100e, and this function as the discharge layer connecting between the channel region 109 and the semiconductor substrate 100. Therefore, accumulation of the positive charge in the channel region 109 can be prevented. To form this discharge layer, spread of the lower diffusion layer 108 needs to be suppressed. Therefore, impurity concentration of the lower diffusion layer 108 needs to be suppressed at a lower level to some extent. As a result, the wiring resistance of the wirings that connect between the lower diffusion layers 108 of the three-dimensional transistors becomes high. However, in the first embodiment, the lower electrodes 104 that short-circuit the lower diffusion layers 108 adjacent in the Y direction are provided. Therefore, the wiring resistance can be decreased while suppressing the impurity concentration of the lower diffusion layers 108.

As explained above, the provision of the discharge layer including the P-type impurity layer 108a and the provision of the lower electrodes 104 that short-circuits the lower diffusion layers 108 have a close relation to each other.

A second embodiment of the present invention is explained next.

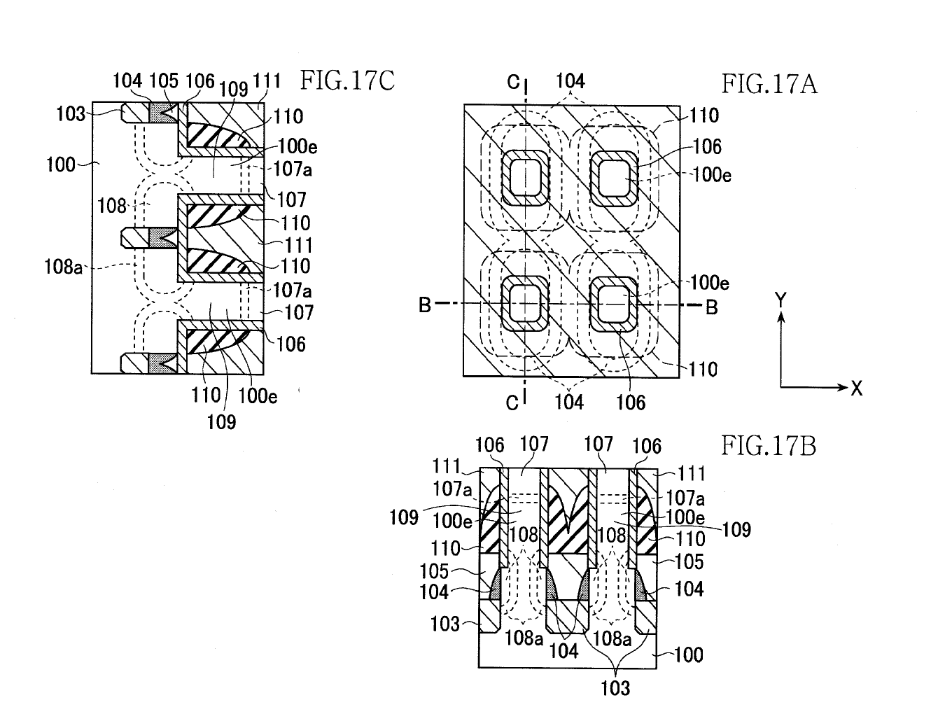

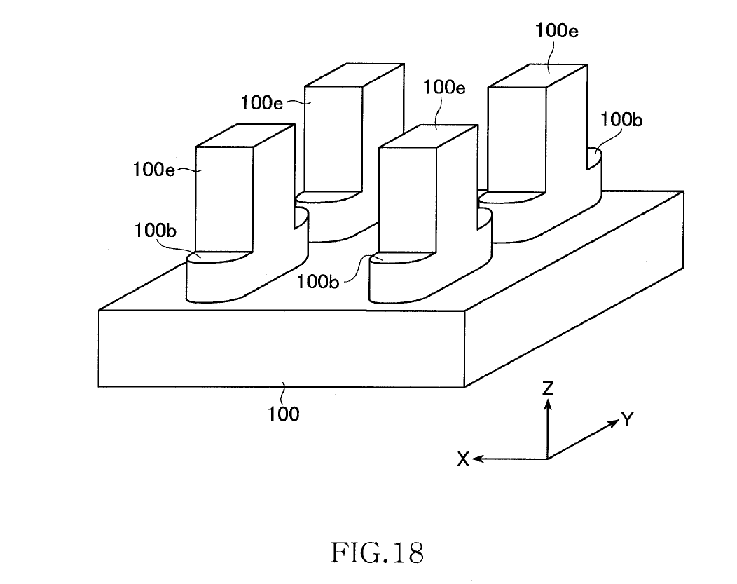

FIGS. 17A to 17C show relevant parts of a semiconductor device according to the second embodiment. FIG. 17A is a top plan view of the semiconductor device, FIG. 17B is a cross-sectional view of FIG. 17A cut along the line B-B, and FIG. 17C is a cross-sectional view of FIG. 17A cut along the line C-C. FIG. 18 is a schematic perspective view for explaining the shape of the semiconductor substrate 100 according to the second embodiment.

As shown in FIGS. 17A to 17C and FIG. 18, in the semiconductor device according to the second embodiment, the projections 100b provided on the semiconductor substrate 100 have island shapes, and are laid out in matrix to the X direction and the Y direction. Each one of semiconductor pillars 100e is provided for each one of island-shaped projections 100b. The planar shape of the projection 100b has an elliptical shape having a larger diameter in the Y direction than a diameter in the X direction. Therefore, the interval between the adjacent projections 100b in the Y direction is smaller than that in the X direction, despite the fact that the layout pitch of the projections 100b in the Y direction is larger than that in the X direction.

In the second embodiment, the lower electrode 104 is also provided on the sidewall of the projection 100b. The lower electrode 104 has a ring shape because the projection 100b has the island shape. Each one of lower electrodes 104 is provided to each one of lower diffusion layers 108. Because the projection 100b has the above-described shape, the lower electrodes 104 adjacent in the Y direction are in contact with each other, and the lower electrodes 104 adjacent in the X direction are not in contact with each other.

Other features of the semiconductor device according to the second embodiment are the same as those of the first embodiment. Therefore, like components are denoted by like reference numerals and explanations thereof will be omitted.

A manufacturing method according to the second embodiment is explained next.

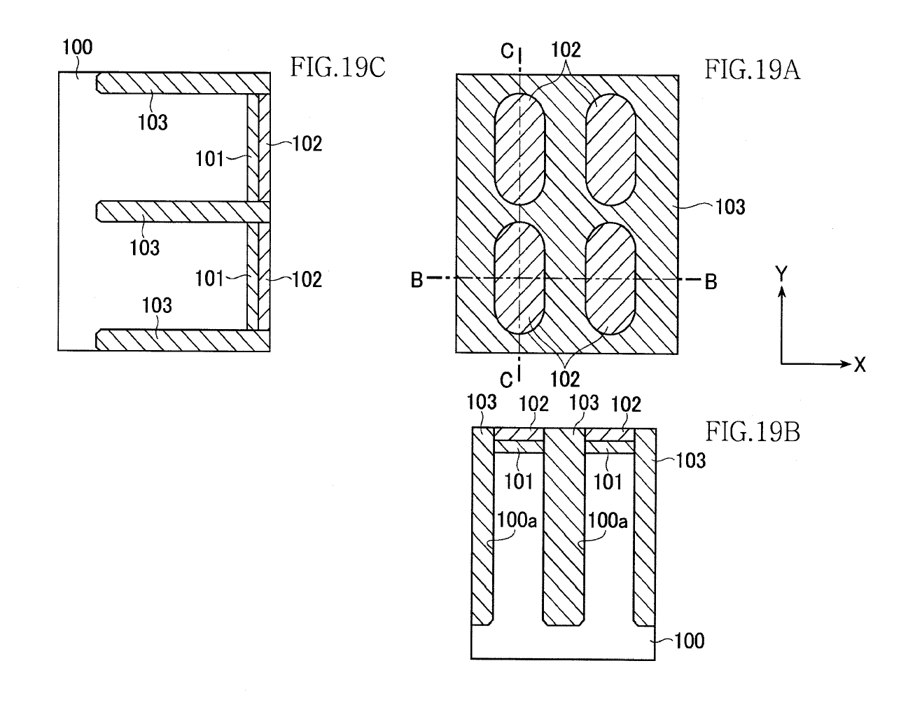

FIGS. 19 to 30 are process views for explaining the manufacturing method of the semiconductor device according to the second embodiment. In each set of these drawings, A expresses a top plan view, B expresses a cross-sectional view cut along the line B-B of A, and C expresses a cross-sectional view cut along the line C-C of A.

First, as shown in FIGS. 19A to 19C, the silicon oxide film 101 and the silicon nitride film 102 are formed on the surface of the semiconductor substrate 100 made of P-type silicon. Thereafter, the silicon nitride film 102 is patterned by dry etching using the photoresist (not shown), thereby keeping the silicon nitride film 102 left in the elliptical shape having a long axis in the Y direction. In this case, the silicon nitride film 102 is patterned into the matrix shape to have a larger layout pitch in the Y direction than in the X direction, and have a smaller interval in the Y direction than in the X direction.

Next, the silicon oxide film 101 and the semiconductor substrate 100 are etched, using the pattered silicon nitride film 102 as a mask, thereby forming the trench 100a within the semiconductor substrate 100.

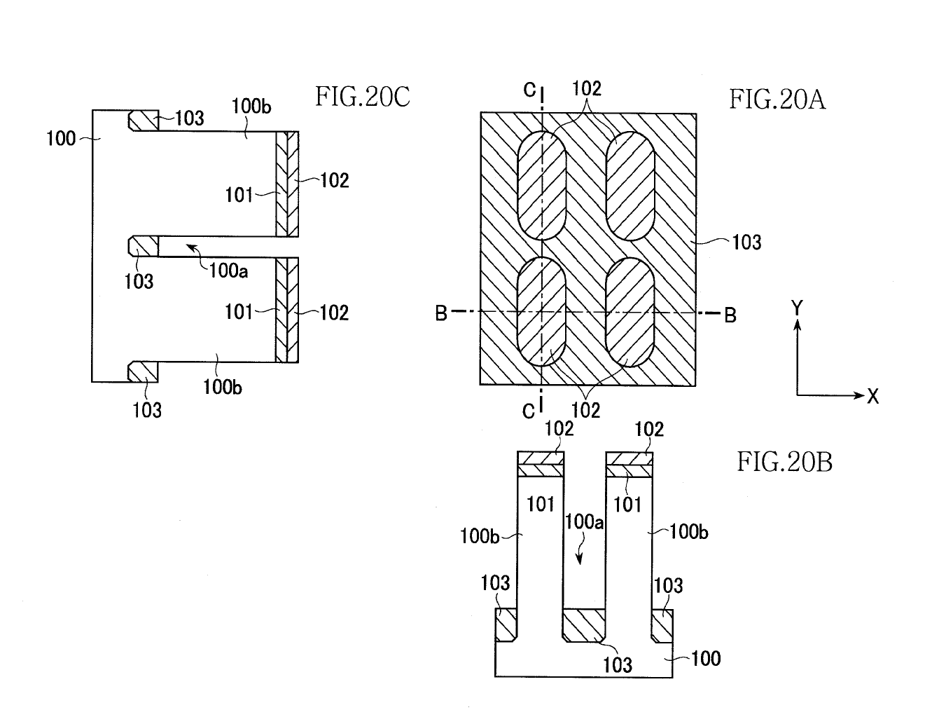

The silicon oxide film 103 is deposited on the whole surface to fill the trench 100a, and the surface is ground using the CMP method, thereby obtaining the structure as shown in FIGS. 19A to 19C. Thereafter, the silicon oxide film 103 is etched back to leave the silicon oxide film 103 at only the bottom of the trench 100a, as shown in FIGS. 20A to 20C. As a result, the matrix-shaped projections 100b are formed on the semiconductor substrate 100.

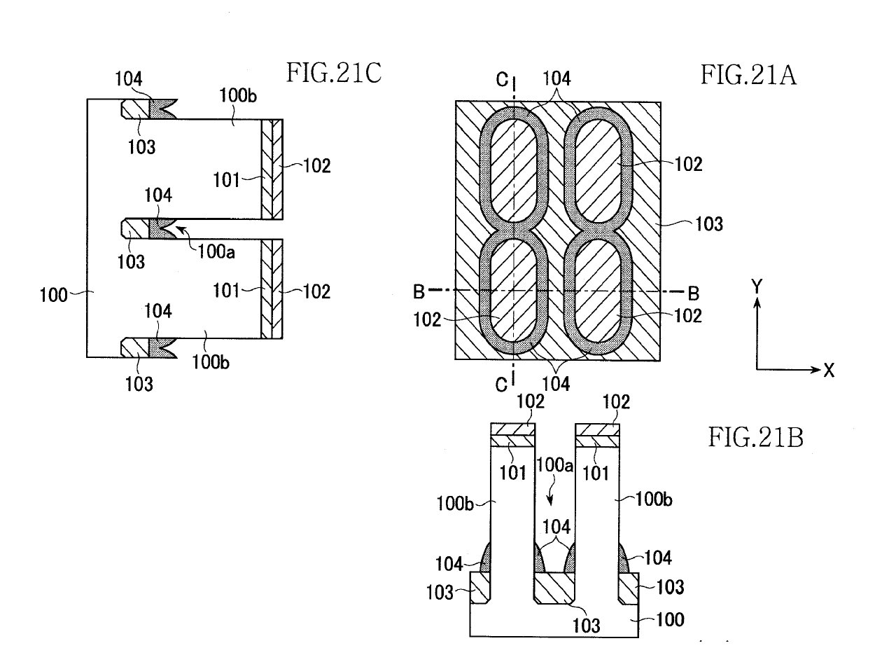

As shown in FIGS. 21A to 21C, the lower electrode material is deposited on the whole surface, and this is etched back. As a result, the lower electrode 104 remains in a ring shape along the sidewall of the projection 100b. In this case, because the interval between the projections 100b adjacent in the Y direction is smaller than that in the X direction, the lower electrodes 104 adjacent in the Y direction are in contact with each other, and the lower electrodes 104 adjacent in the X direction are not in contact with each other.

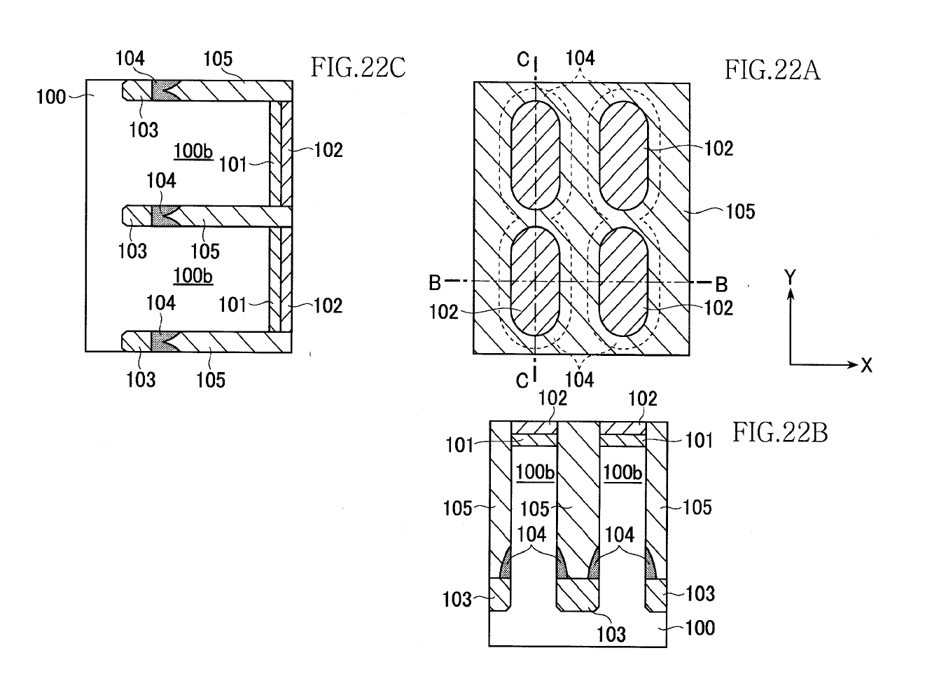

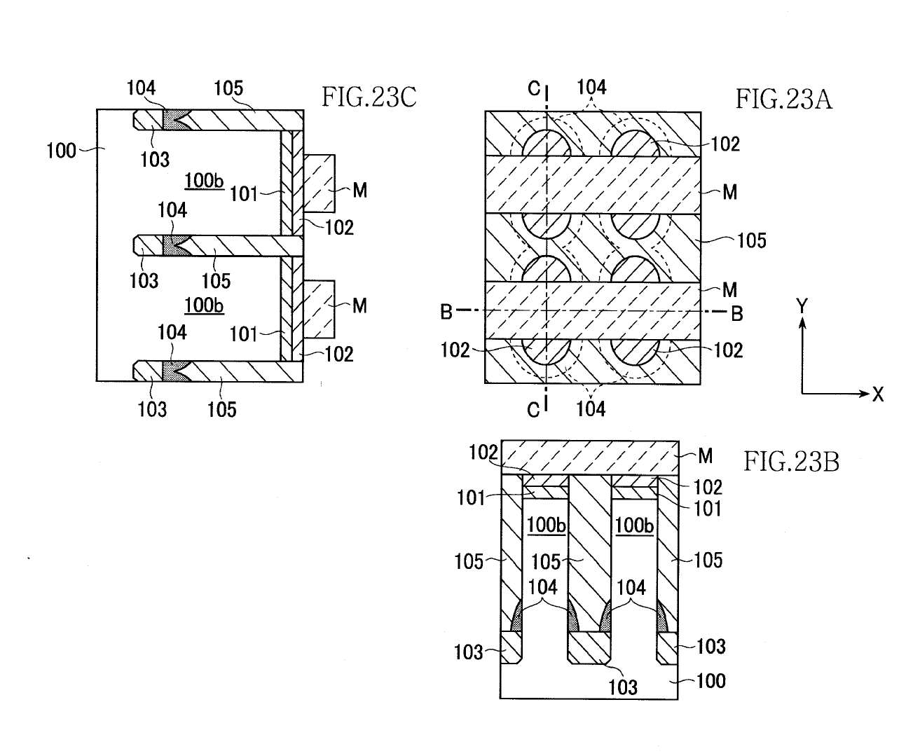

The silicon oxide film 105 is deposited on the whole surface, and then the surface is ground using the CMP method, thereby obtaining the structure as shown in FIGS. 22A to 22C. In this case, the silicon nitride film 102 can be also used as a stopper. Thereafter, the photoresist is exposed to form the belt-shaped mask pattern M extending to the X direction, as shown in FIGS. 23A to 23C. The mask pattern M needs to be formed to intersect with the projection 100b.

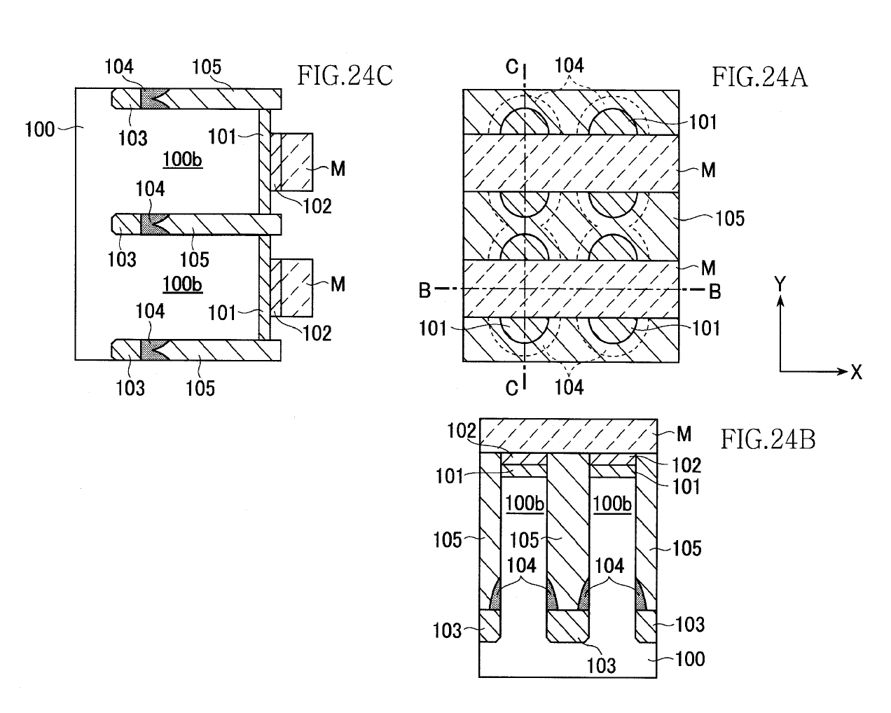

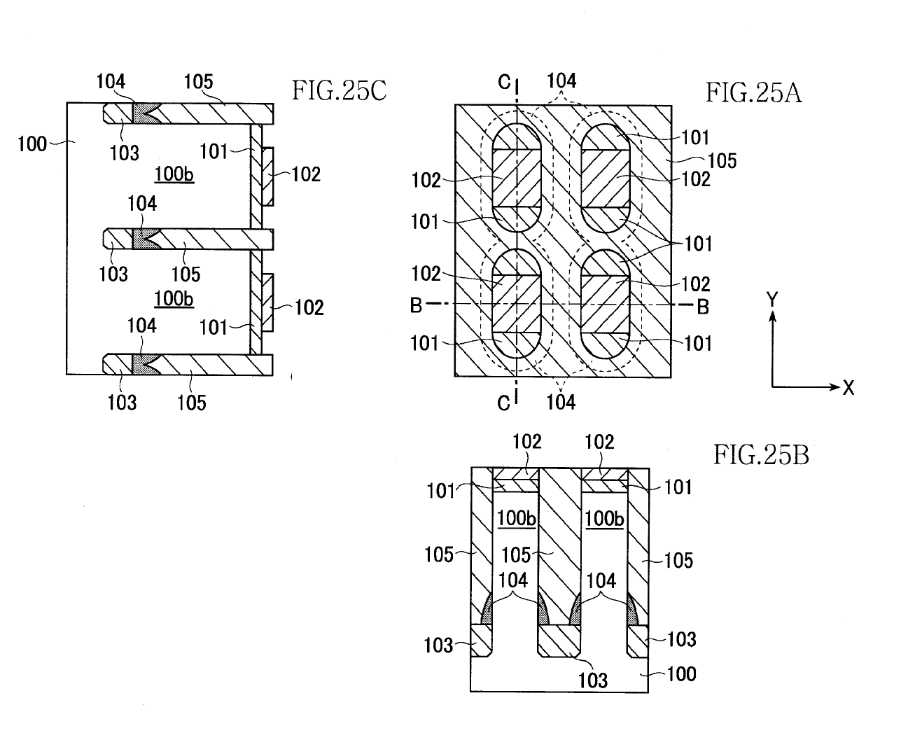

The silicon nitride film 102 is etched using the mask pattern M, as shown in FIGS. 24A to 24C. Accordingly, the edge in the Y direction of the silicon nitride film 102 in the elliptical shape is removed, and, only the center portion remains. Thereafter, the mask pattern M is removed, as shown in FIGS. 25A to 25C.

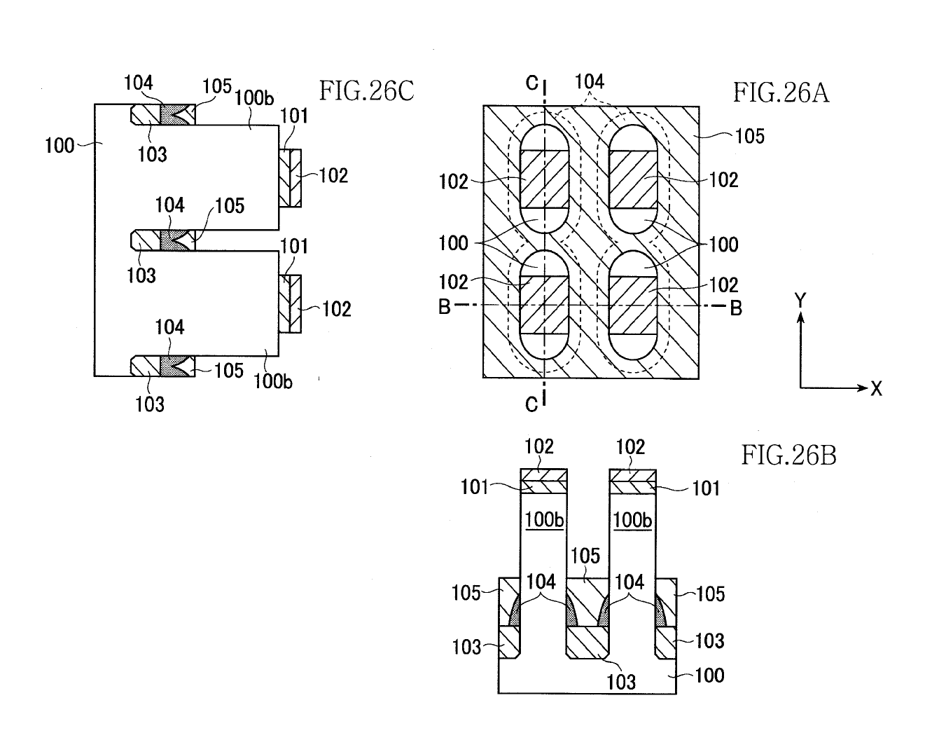

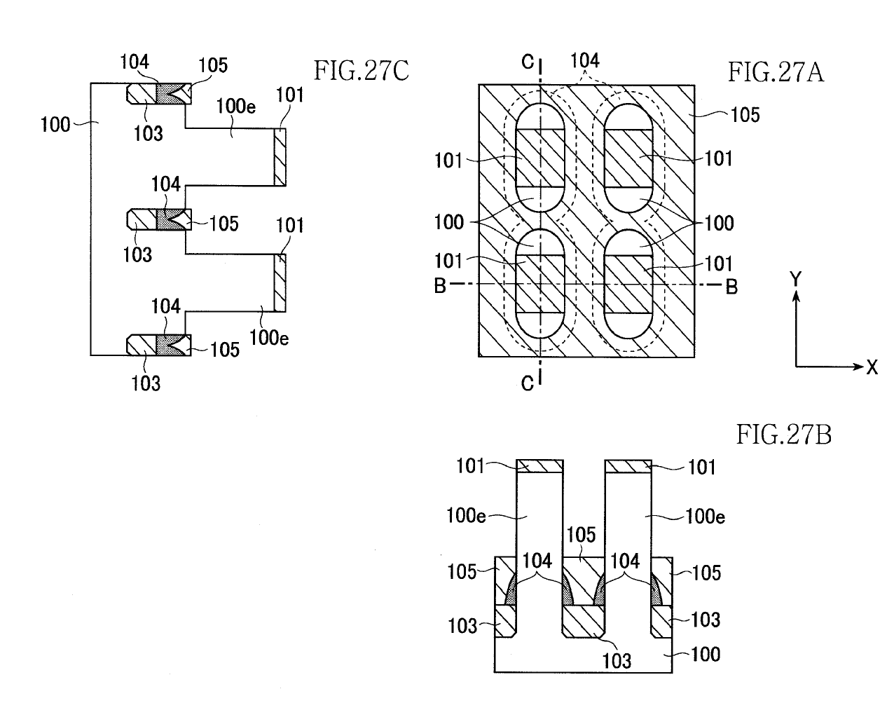

The silicon oxide films 101 and 105 are etched, using the silicon nitride film 102 as a mask, as shown in FIGS. 26A to 26C. In this etching, the etching amount of the silicon oxide film 105 needs to be adjusted so as not to expose the lower electrode 104. As shown in FIGS. 27A to 27C, the semiconductor substrate 100 is etched, using the silicon oxide film 101 as a mask. Accordingly, the end in the Y direction of the projection 100b in the elliptical shape is removed, and plural semiconductor pillars 100e extending to a direction perpendicular to the main surface of the semiconductor substrate 100 are laid out in matrix to the X direction and the Y direction. In other words, the semiconductor substrate 100 has the shape as shown in FIG. 18. The interval between the semiconductor pillars 100e in the X direction becomes smaller than that in the Y direction.

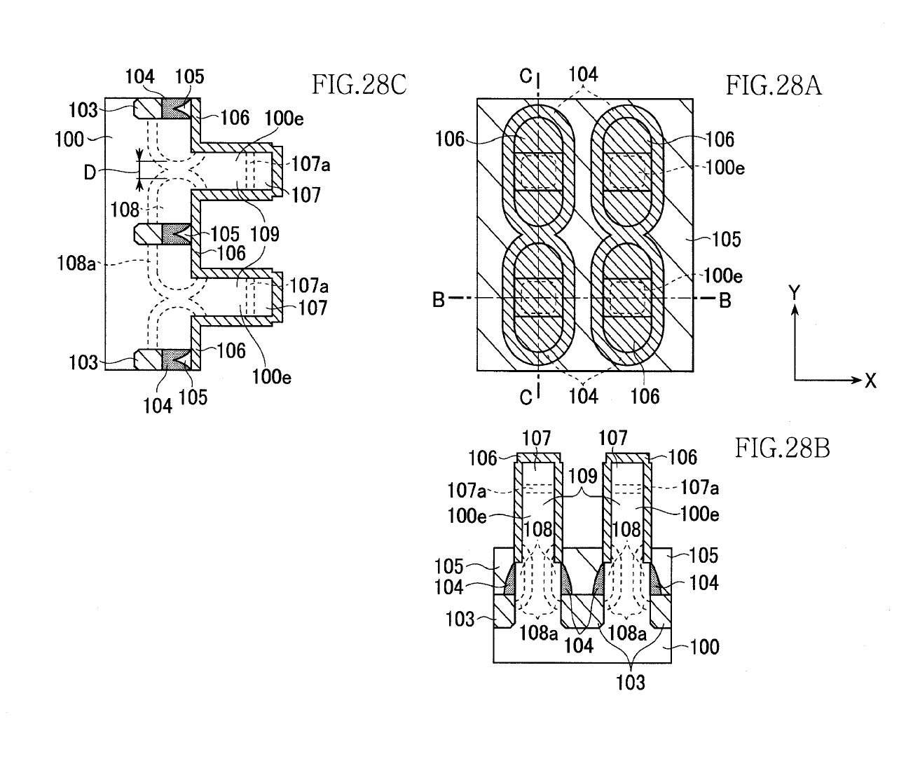

Next, as shown in FIGS. 28A to 28C, the gate insulating film 106 is formed by thermal oxidation on the exposed surface of the semiconductor substrate 100. As a result, all side surfaces of the semiconductor pillar 100e are covered with the gate insulating film 106. The N-type impurity such as phosphorus (P) is ion-implanted into the semiconductor pillar 100e to form the upper diffusion layer 107 and the lower diffusion layer 108 in the upper part and the lower part of the semiconductor pillar 100e, respectively. Further, the P-type impurity such as boron (B) is ion-implanted into the semiconductor pillar 100e to form the P-type impurity layers 107a and 108a in the upper part and the lower part of the semiconductor pillar 100e, respectively. As a result, the P-type impurity layer 108a is formed in the clearance D in which the lower diffusion layer 108 is not presented, and this P-type impurity layer 108a functions as a discharge layer that connects between the channel region 109 and the semiconductor substrate 100, like in the first embodiment.

In this case, it is also preferable to form the diffusion layers 107 and 108 by ion-implanting the N-type impurity, after forming a sacrifice oxide film, and thereafter, form the gate insulating film by thermal oxidation. The upper diffusion layer 107 and the lower diffusion layer 108 can be formed by separate ion implantations. In forming the P-type impurity layer 108a, the P-type impurity layer 107a can be omitted, by providing the injection mask on the upper part of the semiconductor pillar 100e.

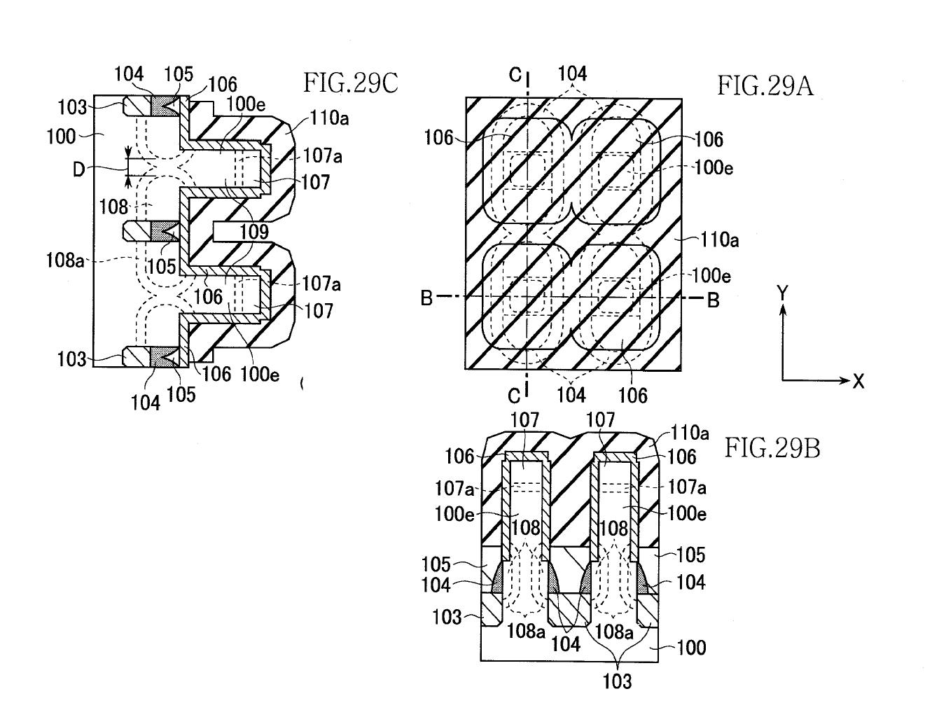

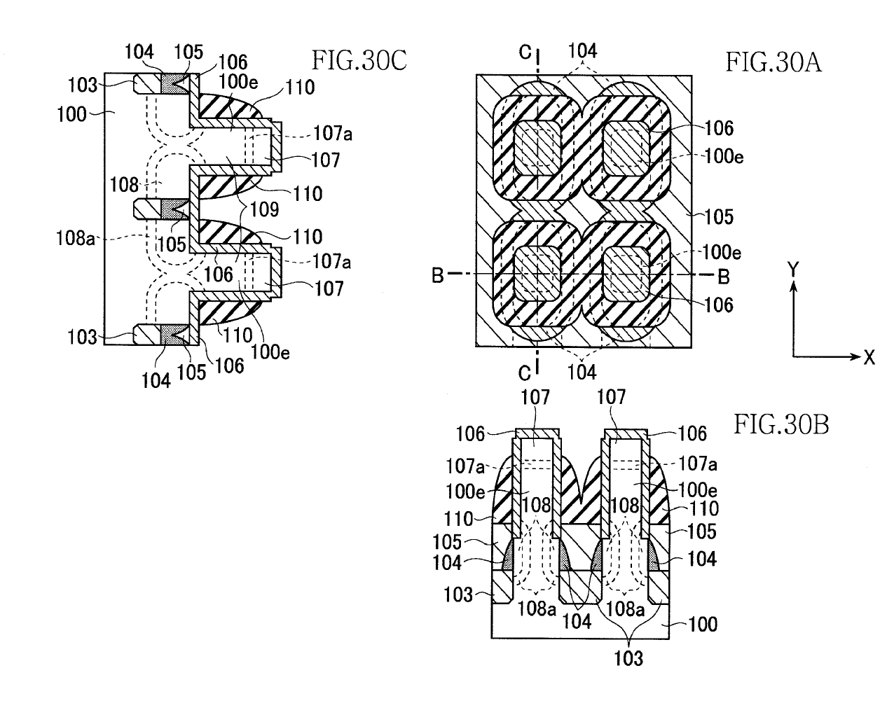

As shown in FIGS. 29A to 29C, the gate electrode material 110a is deposited on the whole surface, thereby covering the whole surface of the semiconductor pillar 100e. As shown in FIGS. 30A to 30C, the gate electrode material 110a is etched back to form the gate electrode 110. The gate electrode material 110a is etched back until when the gate insulating film 106 present between the semiconductor pillar 100e adjacent in the Y direction is exposed. As described above, the interval between the semiconductor pillars 100e in the X direction is set smaller than that in the Y direction. Therefore, by performing the etch back, the gate electrodes 110 adjacent in the Y direction are not in contact with each other, and the gate electrodes 110 adjacent in the X direction are in contact with each other.

The silicon oxide film 111 is deposited on the whole surface, and, this surface is ground using the CMP method, thereby obtaining the structure as shown in FIGS. 17A to 17C.

As explained above, in the semiconductor device according to the second embodiment, each lower electrode 104 has a ring shape, and the lower electrodes 104 adjacent in the Y direction are in contact with each other, and the lower electrodes 104 adjacent in the X direction are not in contact with each other. Accordingly, effects similar to those explained in the first embodiment are obtained. Further, even when a part of the lower electrode 104 is broken, the wiring resistance of the lower electrodes 104 little changes. Therefore, according to the second embodiment, the reliability of the product can be further increased, in addition to obtaining the effect according to the first embodiment.

While a preferred embodiment of the present invention has been described hereinbefore, the present invention is not limited to the aforementioned embodiment and various modifications can be made without departing from the spirit of the present invention. It goes without saying that such modifications are included in the scope of the present invention.

For example, in each of the above embodiments, an N-channel type MOS transistor is formed as a three-dimensional transistor. However, the application of the present invention is not limited to this, and the invention can be also applied to form a P-channel type MOS transistor. Further, other active elements than the MOS transistors can be also formed.

What is claimed is:

1. A method of manufacturing a semiconductor device comprising:
etching a surface of a semiconductor substrate to form a trench in the semiconductor substrate and a projection surrounded by the trench;
forming a lower electrode at a bottom portion of the trench and along sidewalls of the projection;
covering the lower electrode with an insulating film;
forming a semiconductor pillar in the semiconductor substrate by etching a part of the projection;
forming a gate insulating film to cover a surface of the semiconductor pillar; and
forming an upper diffusion layer and a lower diffusion layer in an upper part and a lower part of the semiconductor pillar, respectively, the formed lower diffusion layer contacting the formed lower electrode.

2. The method of manufacturing the semiconductor device of claim 1, wherein the forming the lower electrode comprises forming a lower electrode material on the entire surface of the semiconductor substrate, and etching back the lower electrode material to form the lower electrode along the sidewalls of the projection.

3. The method of manufacturing the semiconductor device of claim 2, wherein the etching back the lower electrode material comprises etching back the lower electrode material without using a mask to form a ring shape lower electrode along the sidewalls of the projection.

4. The method of manufacturing the semiconductor device of claim 1, further comprising:
forming a discharge layer that connects a channel region located between the upper diffusion layer and the lower diffusion layer to the semiconductor substrate.

5. The method of manufacturing the semiconductor device of claim 4, wherein the forming the upper diffusion layer and the lower diffusion layer comprises ion-implanting a first impurity having a first conductive type, and the forming the discharge layer comprises ion-implanting a second impurity, having a second conductive type different from the first conductive type, deeper than the first impurity.

6. The method of manufacturing the semiconductor device of claim 5, wherein the forming the lower diffusion layer by ion-implanting the first impurity comprises forming the lower diffusion layer on a projection located outside of the formed semiconductor pillar.

7. The method of manufacturing the semiconductor device of claim 1, wherein the etching the surface comprises etching the surface of the semiconductor substrate to form the trench in the semiconductor substrate and a plurality of island-shaped projections, surrounded by the trench, the plurality of the island-shaped projections laid out in a matrix extending in a first direction and a second direction, the first and second directions parallel to the surface of the semiconductor substrate.

8. The method of manufacturing the semiconductor device of claim 7, wherein the forming the lower electrode comprises forming a plurality of lower electrodes along sidewalls of the respective plurality of the island-shaped projections in the first and the second directions, and among the plurality of the lower electrodes, lower electrodes adjacent in the first direction are in contact with each other, and lower electrodes adjacent in the second direction are not in contact with each other.

9. The method of manufacturing the semiconductor device of claim 8, wherein an interval between adjacent island-shaped projections, among the plurality of the island-shaped projections, in the first direction is smaller than an interval between adjacent island-shaped projections, among the plurality of the island-shaped projections, in the second direction.

10. The method of manufacturing the semiconductor device of claim 1, the method further comprising:
depositing a silicon oxide film on the bottom portion of the trench prior to forming the lower electrode.

11. The method of manufacturing the semiconductor device of claim 10, wherein the forming the lower electrode comprises forming the lower electrode on the silicon oxide film.

12. A method of manufacturing a semiconductor device, comprising:
forming a semiconductor pillar on a semiconductor substrate, the semiconductor pillar surrounded by a trench in the semiconductor substrate and a lower electrode formed in the trench and surrounding sidewalls of the semiconductor pillar;
forming a gate insulating film covering a surface of the semiconductor pillar;
forming an upper diffusion layer and a lower diffusion layer in an upper part and a lower part of the semiconductor pillar, respectively; and
forming a discharge layer that connects a channel region located between the upper diffusion layer and the lower diffusion layer to the semiconductor substrate.

13. The method of manufacturing the semiconductor device of claim 12, wherein the forming the upper diffusion layer and the lower diffusion layer comprises ion-implanting a first impurity having a first conductive type, and the forming the discharge layer comprises ion-implanting a second impurity, having a second conductive type different from the first conductive type, deeper than the first impurity.

14. The method of manufacturing the semiconductor device of claim 13, wherein the forming the lower diffusion layer by ion-implanting the first impurity comprises forming the lower diffusion layer on a projection located outside of the formed semiconductor pillar.

15. The method of manufacturing the semiconductor device of claim 12, the method further comprising:
depositing a silicon oxide film on a bottom portion of the trench.

16. The method of manufacturing the semiconductor device of claim 15, the method further comprising:
forming the lower electrode on the silicon oxide film at the bottom portion of the trench.
